(19) United States
(12) Patent Application Publication
(10) Pub. No.: US 2012/0248549 A1
(43) Pub. Date: Oct. 4, 2012

(54) Method for Increasing Reverse Breakdown Voltage Between P-Well and N-Well and related Semiconductor Silicon Devices

(75) Inventors: Rongrong Bai, Beijing (CN); Zhongzhi Liu, Beijing (CN); Jing Cao, Rancho Santa Margarita, CA (US); Yihai Xiang, Rancho Santa Margarita, CA (US)

(73) Assignee: BEIJING KT MICRO, LTD., Beijing (CN)

(21) Appl. No.: 13/240,641

(22) Filed: Sep. 22, 2011

(30) Foreign Application Priority Data
Mar. 29, 2011 (CN) 201110076115.5

(51) Int. Cl. H01L 29/78; H01L 21/8234

(52) U.S. Cl. 257/409; 438/275; 257/E29.255; 257/E21.616

(57) ABSTRACT

A method for improving the reverse breakdown voltage between P-well and N-well and related semiconductor silicon devices are described herein. In one aspect, a semiconductor silicon device comprises a substrate; a P-well in said substrate; an N-well in said substrate; wherein said N-well and said P-well are separated by said substrate. In another aspect, a method for increasing the reverse breakdown voltage from P-well to N-well comprises: providing a substrate; forming an N-well and a P-well in said substrate and separating said N-well and said P-well by said substrate.

### RELATED APPLICATIONS INFORMATION

The application claims priority under 35 U.S.C. 119(a) to Chinese application number 201110076115.5, filed on Mar. 29, 2011, which is incorporated herein by reference in its entirety as if set forth in full.

### BACKGROUND

1. Technical Field

The embodiments described herein relate to microelectronics, and more particularly, to a method for increasing reverse breakdown voltage between P-well and N-well and related semiconductor silicon devices.

2. Related Art

In the manufacturing process of the integrated circuit, there exits such a semiconductor silicon device, FIG. 1A is a plan view showing the semiconductor silicon device under the existing technologies. FIG. 1B is a cross-sectional view taken along line AA in FIG. 1A. The semiconductor silicon device includes an N-well 11, a P-well 12 and a P-type substrate 13, the N-well 11 and the P-well 12 are located in the P-type substrate 13, and the N-well 11 is adjacent to the P-well 12. An N+ implant region 111 is formed in the N-well 11, a voltage V₁ is applied to the N-well 11 via the N+ implant region 111, a P+ implant region 121 is formed in the P-well 12, and a voltage V₂ is applied to the P-well 12 via the P+ implant region 121, V₁>V₂.

For example, for the 0.18 um process node, if the differentia between the voltage applied to the N-well 11 and the voltage applied to the P-well 12 exceeds 14 v, the diode formed by the P-well 12 and the N-well 11 would probably break down. In other words, the reverse breakdown voltage for the diode formed by P-well 12 and N-well 11 is only about 14 v.

### SUMMARY

A method for improving the reverse breakdown voltage between P-well and N-well and related semiconductor silicon devices are described herein and the described method increases the reverse breakdown voltage between P-well and N-well.

In one aspect, a method for increasing the reverse breakdown voltage between P-well and N-well, the method comprises providing a substrate; forming an N-well and a P-well, wherein said N-well and said P-well are separated by said substrate.

In another aspect, a semiconductor silicon device comprises: a substrate; a P-well formed in said substrate; an N-well formed in said substrate; wherein said N-well and said P-well are separated by said substrate.

Because the N-well and the P-well are surrounded by the substrate, the N-well and the P-well are not connected directly, and the carrier concentration of the substrate is lower than the carrier concentration of the P-well and the N-well by several orders of magnitude, as a result, the reverse breakdown voltage between P-well and N-well is increased.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1A is a plan view showing a semiconductor silicon device under the existing technologies;

FIG. 1B is a cross-section view taken along line AA in FIG. 1A;

FIG. 2A is a plan view showing a semiconductor silicon device according to a first embodiment;

FIG. 2B is a cross-section view taken along line BB in FIG. 2A;

FIG. 3 is a plan view showing a PMOS transistor according to another embodiment;

FIG. 4 is a cross-sectional view taken along line CC in FIG. 3;

FIG. 5 is a flow chart showing a method for increasing the reverse breakdown voltage between P-well and N-well according to one embodiment;

FIG. 6 is a flow chart showing a method for increasing the reverse breakdown voltage between P-well and N-well according to another embodiment.

### DETAILED DESCRIPTION

Referring now to the drawings, a description will be made herein of embodiments herein.

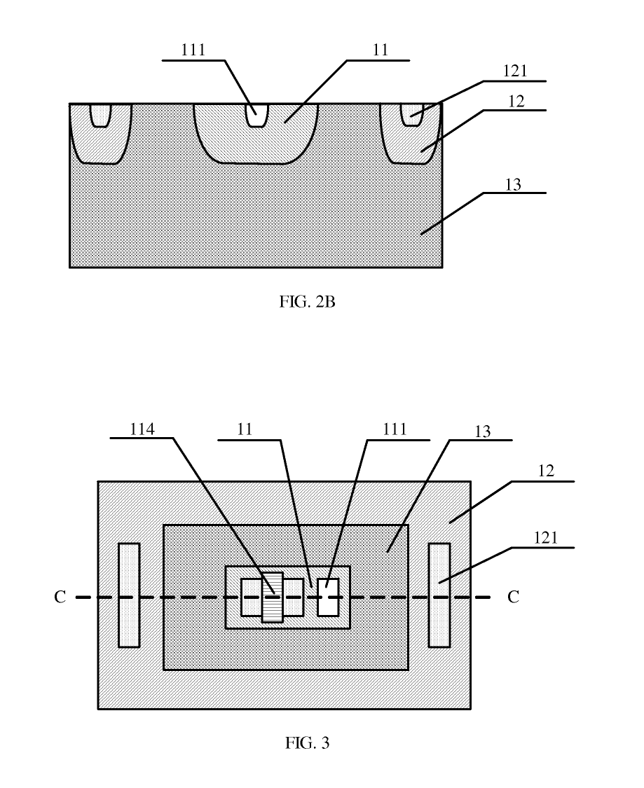

FIG. 2A is a plan view showing a semiconductor silicon device according to a first embodiment; FIG. 2B is a cross-section view taken along line BB in FIG. 2A; the semiconductor silicon device can include an N-well 11, a P-well 12 and a P-type substrate 13. In particular, the N-well 11 and the P-well 12 are formed in the P-type substrate 13, the N-well 11 and P-well 12 are separated by the P-type substrate 13.

In this embodiment, since the N-well 11 is surrounded by the P-type substrate 13 and the carrier concentration of the P-type substrate 13 is lower than the carrier concentration of the P-well 12 by several orders of magnitude, as a result, the reverse breakdown voltage between the P-well 12 and the N-well 11 is increased. In this embodiment, the P-type substrate could separate the N-well and the P-well, and the manufacturing process of the integrated circuit does not need to be changed and associated cost is reduced.

In another embodiment, the P-type substrate may be replaced by an N-type substrate, in this instance, the P-well is surrounded by the N-type substrate and the carrier concentration of the N-type substrate is lower than the carrier concentration of the N-well by several orders of magnitude, as a result, the reverse breakdown voltage between P-well and N-well is increased. Additionally, in this embodiment, the N-type substrate can separate the N-well and the P-well, and the manufacturing process of the integrated circuit does not need to be changed and associated cost is reduced.

In another embodiment, in order to further improve performance, the distance Wₚ between the N-well 11 and the P-well 12 satisfies the following relationship:

$${W}_{P} > {[ \frac{2 {ɛ}_{s}}{q} \frac{1}{{N}_{A}} \frac{( {V}_{BJ} - {V}_{A} )}{( 1 + \frac{{N}_{A}}{{N}_{D}} )} ]}^{\frac{1}{2}}$$

Furthermore, in FIG. 2A and FIG. 2B, in order to apply a voltage on the N-well 11 and the P-well 12, an N+ implant region 111 is formed in the N-well 11 and a P+ implant region 121 is formed in the P-well 12.

In order to further improve performance, the distance W_{N1} between the N+ implant region 111 in the N-well 11 and the edge of N-well 11 satisfies the following relationship:

$${W}_{N 1} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}}$$

In particular, εₛ is the silicon absolute permittivity, q is the electron charge, N_{A} is the doping concentration of the P-type substrate 13, N_{D} is the doping concentration of the N-well 11, V_{BJ} is the built-in potential of the PN junction formed by the N-well 11 and the P-type substrate 13, V_{A} is the potential difference between the P-well 12 and the N-well 11.

For example: when V_{A}=−20V, the distance Wₚ between the N-well 11 and the P-well 12 satisfies the following relationship:

$$\begin{matrix}{W}_{P} > {[ \frac{2 {ɛ}_{s}}{q} \frac{1}{{N}_{A}} \frac{( {V}_{BJ} - {V}_{A} )}{( 1 + \frac{{N}_{A}}{{N}_{D}} )} ]}^{\frac{1}{2}} \approx {[ \begin{matrix}\frac{2 \times 1.04 \times {10}^{- 12}}{1.6 \times {10}^{- 19}} \times \frac{1}{{10}^{15}} \times \\ \frac{20}{( 1 + \frac{{10}^{15}}{3 \times {10}^{17}} )}\end{matrix} ]}^{\frac{1}{2}} \\ = 5.1 \times {10}^{- 4} cm \\ = 5.1 um\end{matrix}$$

The distance W_{N1} between the N+ implant region 111 in the N-well 11 and the edge of N-well 11 satisfies the following relationship:

$$\begin{matrix}{W}_{N 1} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} \approx {[ \begin{matrix}\frac{2 \times 1.04 \times {10}^{- 12}}{1.6 \times {10}^{- 19}} \times \frac{1}{3 \times {10}^{17}} \times \\ \frac{20}{( 1 + \frac{3 \times {10}^{17}}{{10}^{15}} )}\end{matrix} ]}^{\frac{1}{2}} \\ = 1.7 \times {10}^{- 6} cm \\ = 0.017 um\end{matrix}$$

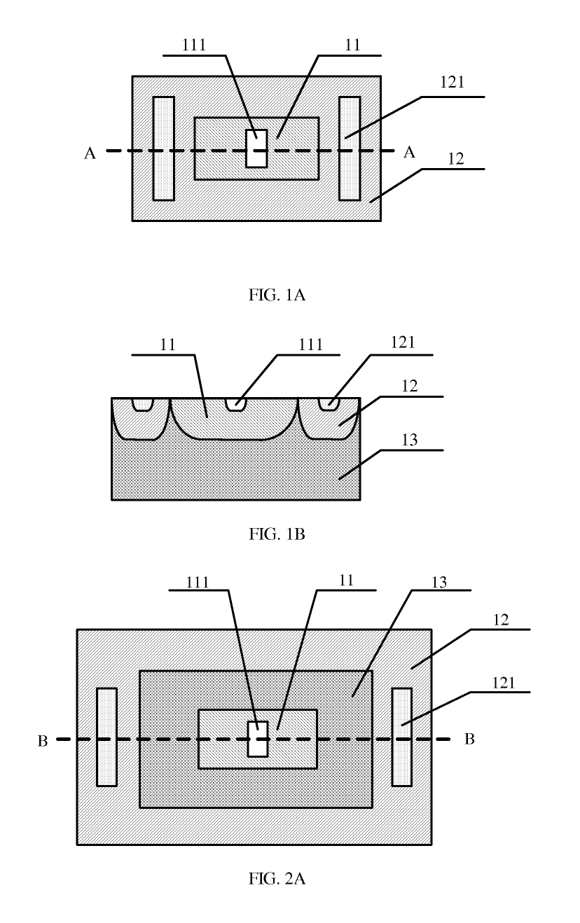

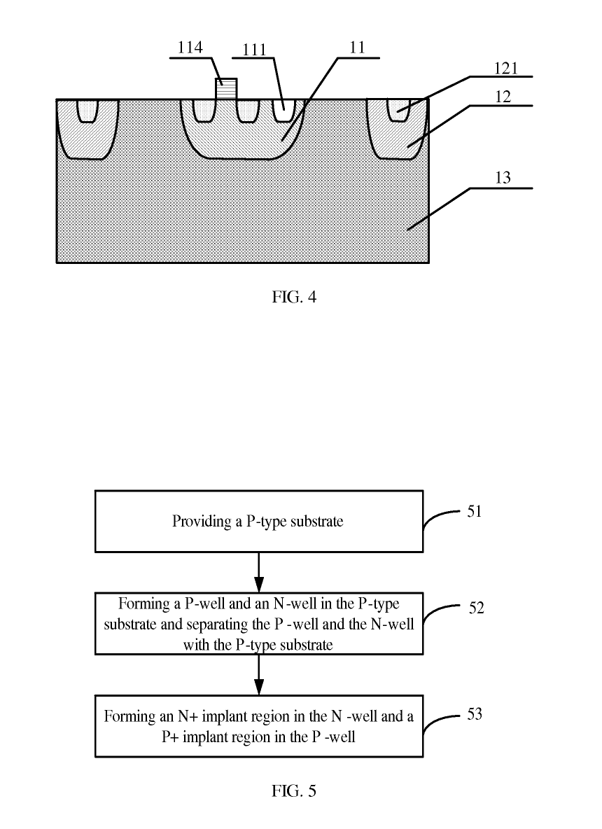

Furthermore, a PMOS transistor is provided to further illustrate this embodiment. FIG. 3 is a plan view showing a PMOS transistor according to another embodiment; FIG. 4 is a cross-sectional view taken along line CC in FIG. 3. The differences from FIGS. 1A and 1B include that two P+ implant regions are further formed in the N-well 11, a polysilicon gate 114 is further formed on the N-well 11, the polysilicon gate 114 is formed between the two P+ implant regions.

In one embodiment, for the PMOS transistor illustrated in FIG. 3 and FIG. 4, the distance W_{N2} between the P+ implant region in the N-well 11 and the edge of the N-well 11 satisfies the following relationship:

$${W}_{N 2} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}}$$

In another embodiment, the distance between the edge of the N-well 11 and any device in the N-well 11 is greater than a pre-determined value and the pre-determined value is equal to

$${[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} .$$

In this embodiment, since the N-well is surrounded by the P-type substrate and the carrier concentration of the P-type substrate is lower than the carrier concentration of the P-well by several orders of magnitude, as a result, the reverse breakdown voltage between P-well and N-well is increased. Additionally, in this embodiment, the P-type substrate can be applied to separate the N-well and the P-well, the manufacturing process of the integrated circuit does not need to be changed and associated cost is reduced.

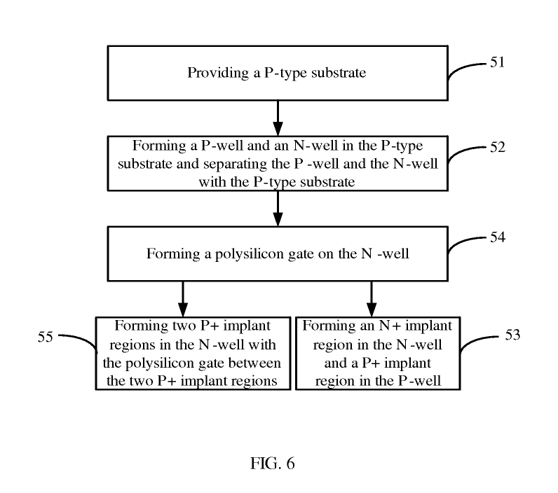

FIG. 5 is a flow chart showing a method for increasing the reverse breakdown voltage between P-well and N-well according to one embodiment.

In step 51, a P-type substrate is provided.

In step 52, an N-well and a P-well are formed in and separated by the P-type substrate. In one embodiment, an N-well is first formed in the silicon substrate and a separation zone is delineated around the N-well. Then a P-well is formed in the silicon substrate with the separation zone separating the N-well and the P-well. In one embodiment, a P-well is first formed in the silicon substrate and a separation zone is delineated around the P-well. Then an N-well is formed in the silicon substrate with the separation zone separating the N-well and P-well.

In this embodiment, since the N-well is surrounded by the P-type substrate and the carrier concentration of the P-type substrate is lower than the carrier concentration of the P-well by several orders of magnitude, as a result, the reverse breakdown voltage between the P-well and the N-well is increased. Additionally, in this embodiment, the P-type substrate can be applied to separate the N-well and the P-well, the manufacturing process of the integrated circuit does not need to be changed and associated cost is reduced.

In another embodiment, the P-type substrate can be replaced by an N-type substrate, in this case, the P-well is surrounded by the N-type substrate and the carrier concentration of the N-type substrate is lower than the carrier concentration of the N-well by several orders of magnitude, as a result, the reverse breakdown voltage between P-well and N-well is increased. Additionally, in this embodiment, the P-type substrate can be applied to separate the N-well and the P-well, the manufacturing process of the integrated circuit does not need to be changed and associated cost is reduced.

FIG. 6 is a flow chart showing a method for increasing the reverse breakdown voltage between P-well and N-well according to another embodiment. Based on the embodiments as illustrated in FIG. 5, in order to further improve the performance, in step 52, the distance Wₚ between N-well and P-well is calculated as follows:

$${W}_{P} > {[ \frac{2 {ɛ}_{s}}{q} \frac{1}{{N}_{A}} \frac{( {V}_{BJ} - {V}_{A} )}{( 1 + \frac{{N}_{A}}{{N}_{D}} )} ]}^{\frac{1}{2}}$$

In particular, εₛ is the silicon absolute permittivity, q is the electron charge, N_{A} is the doping concentration of the P-type substrate, N_{D} is the doping concentration of the N-well, V_{BJ} is the built-in potential of the PN junction formed by the N-well and the P-type substrate, V_{A} is the potential difference between the P-well and the N-well.

In this embodiment, in order to apply voltage on the N-well 11 and the P-well 12, the following step can be included after the step 52:

In step 53, an N+ implant region is formed in the N-well and a P+ implant region is formed in the P-well.

In one embodiment, in the step 53, the distance W_{N1} between the N+ implant region in the N-well and the edge of N-well is calculated according to the formula:

$${W}_{N 1} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}}$$

Furthermore, forming a PMOS transistor is provided to further illustrate this embodiment. As illustrated in FIG. 6, in order to form a PMOS transistor, the following steps can be included before the step 53:

In step 54, a polysilicon gate is formed on the N-well.

In step 55, two P+ implant regions are formed in the N-well and the polysilicon gate is located in an area between the two P+ implant regions.

It is noted that, there is no strict timing relationship between the step 55 and the step 53.

In one embodiment, in the step 55, the distance W_{N2} between the P+ implant region in the N-well and the edge of the N-well satisfies the following relationship:

$${W}_{N 2} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}}$$

In another embodiment, the distance between the edge of the N-well 11 and any device in the N-well 11 is greater than a pre-determined value and the pre-determined value is equal to

$${[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} .$$

In this embodiment, since the N-well is surrounded by the P-type substrate and the carrier concentration of the P-type substrate is lower than the carrier concentration of the P-well by several orders of magnitude, as a result, the reverse breakdown voltage between P-well and N-well is increased. Additionally, this embodiment only needs to apply the P-type substrate to separate the N-well and the P-well, the manufacturing process of the integrated circuit does not needs to be changed and associated cost is reduced.

While certain embodiments have been described above, it will be understood that the embodiments described are by way of example only. Accordingly, the systems and methods described herein should not be limited based on the described embodiments Rather, the systems and methods described herein should only be limited in light of the claims that follow when taken in conjunction with the above description and accompanying drawings.

What is claimed is:

1. A method for increasing the reverse breakdown voltage between P-well and N-well, the method comprising:
providing a substrate;
forming an N-well and a P-well in said substrate and separating said N-well and said P-well by said substrate.

2. The method of claim 1, wherein the substrate is a P-type substrate.

3. The method of claim 2, wherein:
the distance Wₚ between said N-well and said P-well is calculated based on the following:
$${W}_{P} > {[ \frac{2 {ɛ}_{s}}{q} \frac{1}{{N}_{A}} \frac{( {V}_{BJ} - {V}_{A} )}{( 1 + \frac{{N}_{A}}{{N}_{D}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.

4. The method of claim 2, wherein the method further comprises:
forming an N+ implant region in said N-well and forming a P+ implant region in said P-well.

5. The method of claim 4, wherein the distance W_{N1} between said N+ implant region in said N-well and the edge of said N-well is calculated based on the following:
$${W}_{N 1} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.

6. The method of claim 4, wherein before the step of forming an N+ implant region in said N-well and forming a P+ implant region in said P-well further comprising: forming a polysilicon gate on said N-well; and
after the step of forming a polysilicon gate on said N-well further comprising: forming two P+ implant regions in said N-well with said polysilicon gate between said two P+ implant regions.

7. The method of claim 6, wherein the distance W_{N2} between said P+ implant region in said N-well and the edge of said N-well is calculated as follow:
$${N}_{N 2} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.

8. A semiconductor silicon device comprising:
a substrate;
a P-well formed in said substrate; and
an N-well formed in said substrate;
wherein said N-well and said P-well are separated by said substrate.

9. The semiconductor silicon device according to claim 8, wherein the substrate is a P-type substrate.

10. The semiconductor silicon device according to claim 9, wherein: the distance Wₚ between said N-well and said P-well is calculated based on the following:
$${W}_{P} > {[ \frac{2 {ɛ}_{s}}{q} \frac{1}{{N}_{A}} \frac{( {V}_{BJ} - {V}_{A} )}{( 1 + \frac{{N}_{A}}{{N}_{D}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.

11. The semiconductor silicon device according to claim 9, further comprising:
a P+ implant region formed in said P-well; and
an N+ implant region formed in said N-well.

12. The semiconductor silicon device according to claim 11, the distance W_{N1} between said N+ implant region in said N-well and the edge of said N-well is calculated based on the following:
$${W}_{N 1} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.

13. The semiconductor silicon device according to claim 11, further comprising:
two P+ implant regions formed in said N-well; and
a polysilicon gate formed on said N-well with said polysilicon gate between said two P+ implant regions.

14. The semiconductor silicon device according to claim 13, wherein the distance W_{N2} between said P+ implant region in said N-well and the edge of said N-well is calculated as follow:
$${W}_{N 2} > {[ \frac{2 {ɛ}_{s}}{q} \frac{1}{{N}_{D}} \frac{( {V}_{BJ} - {V}_{A} )}{( 1 + \frac{{N}_{D}}{{N}_{A}} )} ]}^{\frac{1}{2}} ,$$
wherein εₛ is the silicon absolute permittivity, q is the electron charge, N_{A} is the doping concentration of said P-type substrate, N_{D} is the doping concentration of said N-well, V_{BJ} is the built-in potential of the PN junction formed by said N-well and said P-type substrate, V_{A} is the potential difference between said P-well and said N-well.
